(19) United States
(12) Patent Application Publication
(10) Pub. No.: US 2011/0079919 A1
(43) Pub. Date: Apr. 7, 2011

(54) ELECTRICAL CONNECTION VIA FOR THE SUBSTRATE OF A SEMICONDUCTOR DEVICE

(75) Inventors: Hamed Chaabouni, Grenoble (FR); Lionel Cadix, Grenoble (FR)

(73) Assignee: STMICROELECTRONICS (CROLLES 2) SAS, Crolles Cedex (FR)

(21) Appl. No.: 12/897,439

(22) Filed: Oct. 4, 2010

(30) Foreign Application Priority Data
Oct. 5, 2009 (FR) 0956930

(51) Int. Cl. H01L 23/48; H01L 21/768

(52) U.S. Cl. 257/774; 438/675; 257/E23.011; 257/E21.577

(57) ABSTRACT

An electrical connection via passing through a substrate for a semiconductor device is made of at least one conducting ring formed in an annular hole passing through the substrate.

### PRIORITY CLAIM

This application claims priority from French Application for Patent No. 09-56930 filed Oct. 5, 2009, the disclosure of which is hereby incorporated by reference.

### TECHNICAL FIELD

The present invention relates to the field of semiconductor devices.

### BACKGROUND

Since semiconductor devices are becoming increasingly complex, it may be advantageous to make electrical connections through substrates, generally made of silicon, on which the semiconductor devices are produced, so as to make electrical connections from one face to the other.

### SUMMARY

What is proposed is a process for producing an electrical connection via through a substrate in order to make an electrical connection from one face of the substrate to the other.

The process may comprise the production of an annular hole in the substrate and the filling of the annular hole with an electrically conductive material in order to obtain a conducting ring at least partly forming the via.

The process may comprise the production of several concentric annular holes and the filling of these annular holes with an electrically conductive material in order to obtain several conducting rings at least partly forming the via.

The process may comprise the production of a central hole and, coaxially with the central hole, at least one annular hole and the filling of the central hole and of the annular hole with an electrically conductive material in order to obtain a central cylinder and, coaxially with said cylinder, at least one ring, at least partly forming the via.

The process may comprise the formation of an auxiliary layer on one face of the substrate and the production of said via from the other face of the substrate up to or right into this auxiliary layer.

The process may comprise the production of said via in a portion of the thickness of the substrate, from one face of the substrate and the removal of a portion of the thickness of the substrate from the other face of the latter in order to expose said via.

The process may comprise the interposition of an insulating material between the substrate and the via.

The radial thickness of each hole is chosen to be at most twice the skin depth (δ) in the material forming the via.

The diameter of the central hole is chosen to be at most twice the skin depth (δ) in the material forming the via.

Also proposed is a substrate for a semiconductor device, comprising at least one via for electrical connection from one face to the other, made of an electrically conductive material.

This electrical connection via may comprise at least one conducting ring made in an annular hole passing through the substrate.

Said via may comprise several coaxially conducting rings, these being made in several coaxial annular holes passing through the substrate.

Said via may comprise a conducting central cylinder and, coaxially with said cylinder, at least one conducting ring, these being made in a central hole and an annular hole passing through the substrate.

The radial thickness of each conducting ring may be at most twice the skin depth (δ) in the material forming the via.

The diameter of the conducting central cylinder may be at most twice the skin depth (δ) in the material forming the via.

Also proposed is a substrate for a semiconductor device, comprising at least one via for electrical connection from one face to the other, made of an electrically conductive material, each portion of this via having a thickness at most twice the skin depth (δ) in the material forming the via.

Also proposed is a semiconductor device comprising a substrate as defined above and, on one face of this substrate, an integrated circuit connected to said via.

### BRIEF DESCRIPTION OF THE DRAWINGS

Semiconductor devices will now be described by way of non-limiting examples and illustrated by the drawing in which:

FIG. 1 shows a partial transverse section of a semiconductor device in the zone of an electrical connection via;

FIG. 2 shows a section on the line II-II of the semiconductor device of FIG. 1;

FIGS. 3 to 5 show sections of the semiconductor device of FIG. 1, according to respective fabrication steps;

FIG. 6 shows a partial section of an alternative embodiment of the semiconductor device of FIG. 1;

FIG. 7 shows a section on the line VII-VII of the semiconductor device of FIG. 6;

FIGS. 8 to 11 show sections of the semiconductor device of FIG. 6, according to respective fabrication steps;

FIG. 12 shows a partial transverse section of a semiconductor device in the zone of another electrical connection via;

FIG. 13 shows a section on the line XIII-XIII of the semiconductor device of FIG. 12;

FIG. 14 shows a partial transverse section of a semiconductor device in the zone of another electrical connection via;

FIG. 15 shows a cross section on the line XIV-XIV of the semiconductor device of FIG. 14;

FIG. 16 shows a partial transverse section of a semiconductor device in the zone of another electrical connection via; and

FIGS. 17 to 21 show sections of the semiconductor device of FIG. 16, according to respective fabrication steps.

### DETAILED DESCRIPTION OF THE DRAWINGS

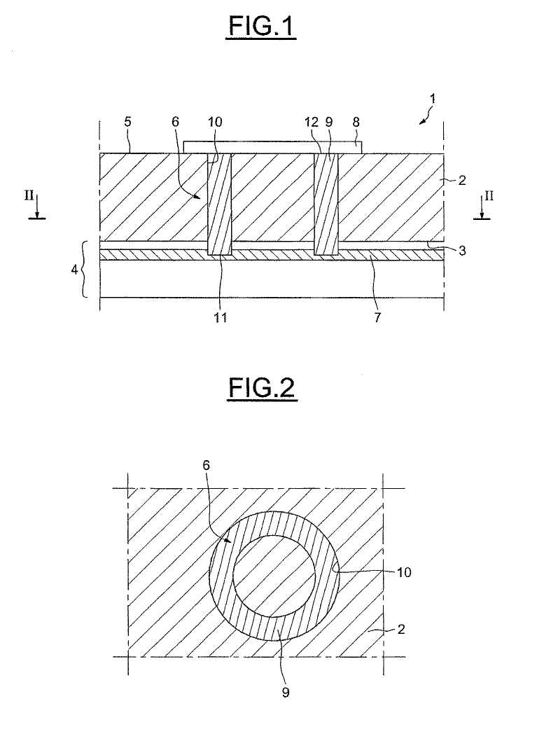

According to one embodiment, illustrated in FIGS. 1 and 2, a semiconductor device 1 comprises a substrate 2 in the form of a wafer, for example a silicon wafer, on a front face 3 of which substrate there are produced, in a front layer 4, integrated circuits and interconnect means.

For example to electrically connect these integrated circuits between the front face 3 and the rear face 5 of the substrate 2, in one direction or the other, said substrate is traversed by an electrical connection via 6 so as, for example, to provide a link between a front pad 7 of the interconnect means of the front layer 4 and a rear pad 8 of interconnect means provided on the rear face 5 of the substrate 2, the front pad 7 being for example in the first metal level of the interconnect means.

The electrical connection via 6 comprises a cylindrical ring 9 made of an electrically conductive material, which fills a cylindrical annular hole 10 produced through the substrate 2, from one face to the other, in such a way that this conducting ring 9 has a front radial face 11 in contact with the front pad 7 and a rear radial face 12 flush with the rear face 5 of the substrate 2 and in contact with the rear pad 8.

The electrical connection via 6 may be produced, in the following manner, by any suitable known means commonly used in microelectronics.

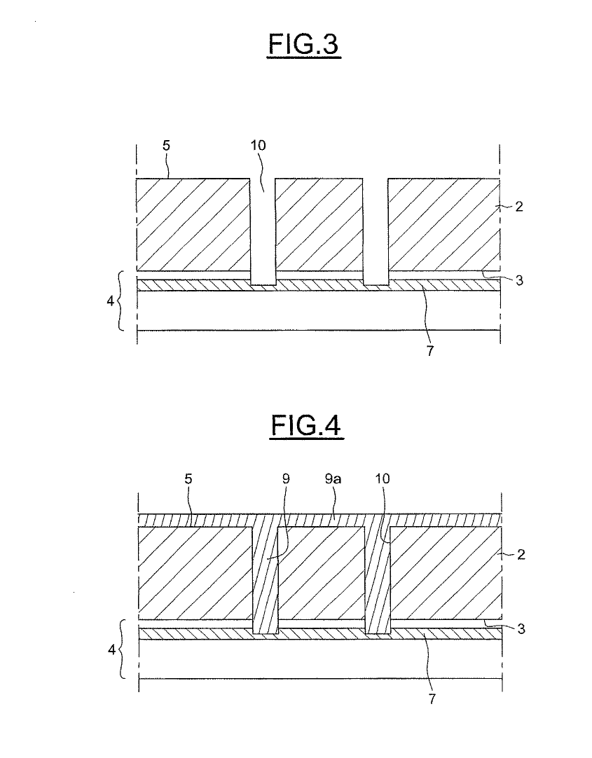

As shown in FIG. 3, for a substrate 2 provided with the front layer 4, the annular hole 10 is produced, for example by etching, starting from the rear face 5. Advantageously, this annular hole 10 may extend slightly into the front pad 7.

Next, as shown in FIG. 4, the annular hole 10 is filled with the material that has to form the conducting ring 9, for example by depositing said material on the front pad 7. This filling operation generally produces a residual layer 9a on the rear face 5 of the substrate 2.

Of course, a plurality of electrical connection vias 6 may be produced at the same time.

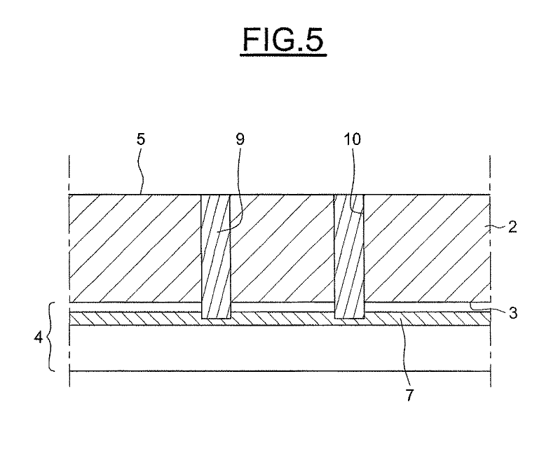

Next, as shown in FIG. 5, the residual layer 9a is removed, for example by CMP (chemical-mechanical polishing), in order to expose the rear face 5 of the substrate 2 and form the rear radial face 12 of the conducting ring 9 in the plane of the rear face 5.

After this, the rear interconnect means may be produced on the rear face 5 of the substrate 2, these comprising the rear pad 8 on the via 6, as shown in FIG. 1.

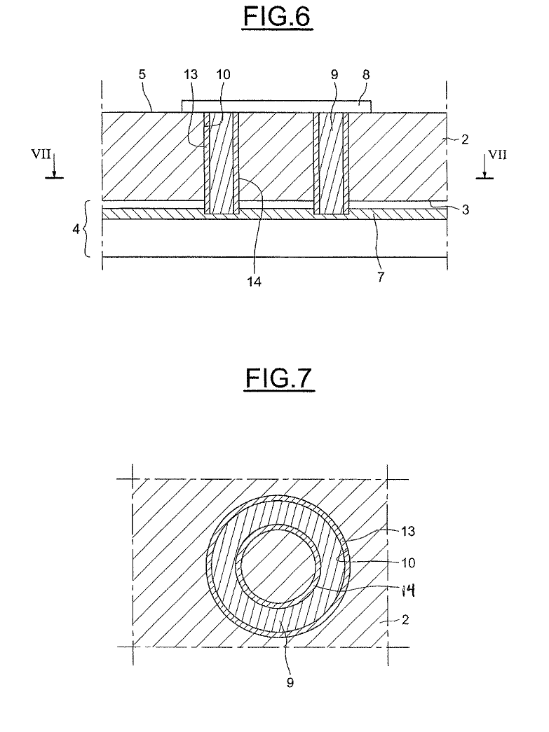

In an alternative embodiment, illustrated in FIGS. 6 and 7, an outer ring 13 and an inner ring 14 made of an insulating material may be interposed between, respectively, the outer and inner walls of the annular hole 10 and the outer and inner walls of the conducting ring 9. This may be the case in particular if the material of the conducting ring 9 may diffuse into the material of the substrate 2.

To produce the outer and inner insulating rings 13 and 14, the following procedure may be carried out by any suitable known means commonly used in microelectronics.

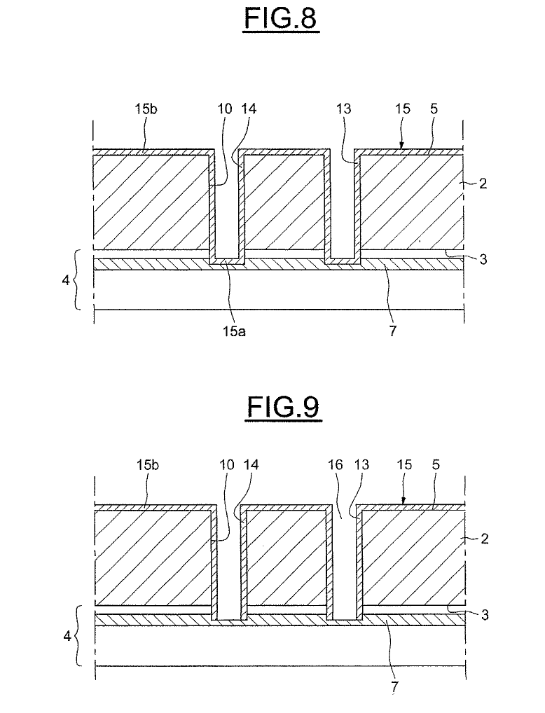

As shown in FIG. 8, for the substrate 2 provided with the front layer 4 and having the annular through-hole 10, a layer 15 of an insulating material is deposited. This layer 15 covers the cylindrical walls of the annular hole 10 so as to form the insulating rings 13 and 14 and has a portion 15a on the pad 7 on the bottom of the hole 10 and a portion 15b on the front face 5 of the substrate 2.

Next, as shown in FIG. 9, the portion 15a of the layer 15 located at the bottom of the annular hole 16 left in this layer 15 is removed so as to expose the front pad 7.

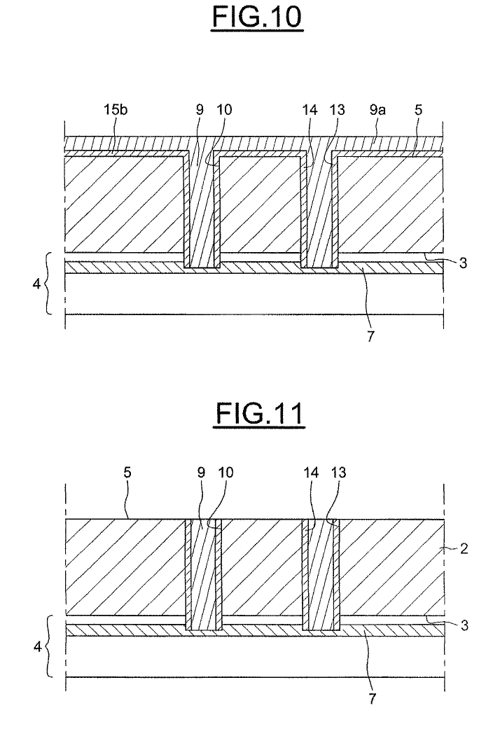

Next, as shown in FIG. 10, the annular hole 16 is filled, as described above in regard to FIG. 4, in order to form the conducting ring 9 on the front pad 7, thereby producing a residual layer 9a on the portion 15b of the layer 15.

Next, as shown in FIG. 11, the residual layer 9a and the portion 15a are removed, as described above with regard to FIG. 5, in order to expose the rear face 5 of the substrate 2.

Thus, the conducting ring 9 and the insulating rings 13 and 14 have front radial faces in contact with the front pad 7 of the substrate 2 and radial rear faces lying in the plane of the rear face 5 of the substrate 2 in at least the thickness of the substrate 2.

The existence of the insulating rings 13 and 14 may be useful for preventing the material forming the conducting ring 9 from being able to diffuse into the material forming the substrate 2.

The rear pad 8 is then produced on the rear face, as described above.

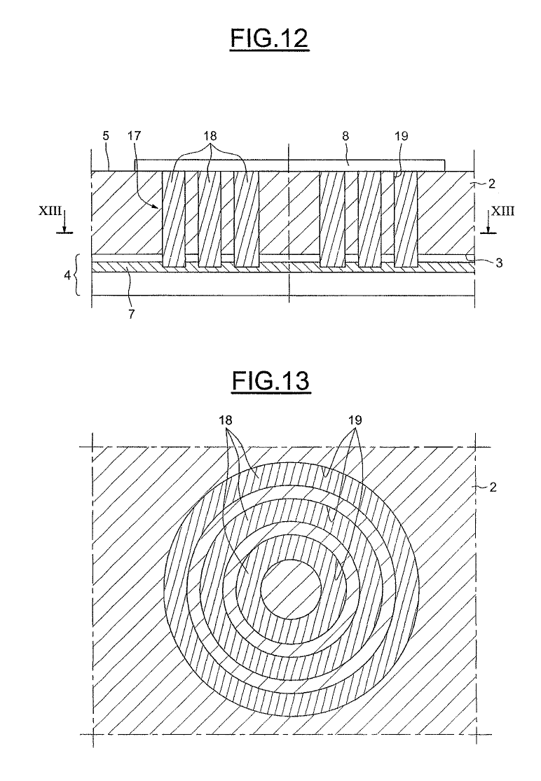

According to an alternative embodiment, illustrated in FIGS. 12 and 13, an electrical connection via 17, designed for connecting a front pad 7 to a rear pad 8 through the substrate 2, may comprise a plurality of coaxial cylindrical rings 18, for example three such rings, which are formed in a plurality of coaxial annular holes 19 made through the substrate 2.

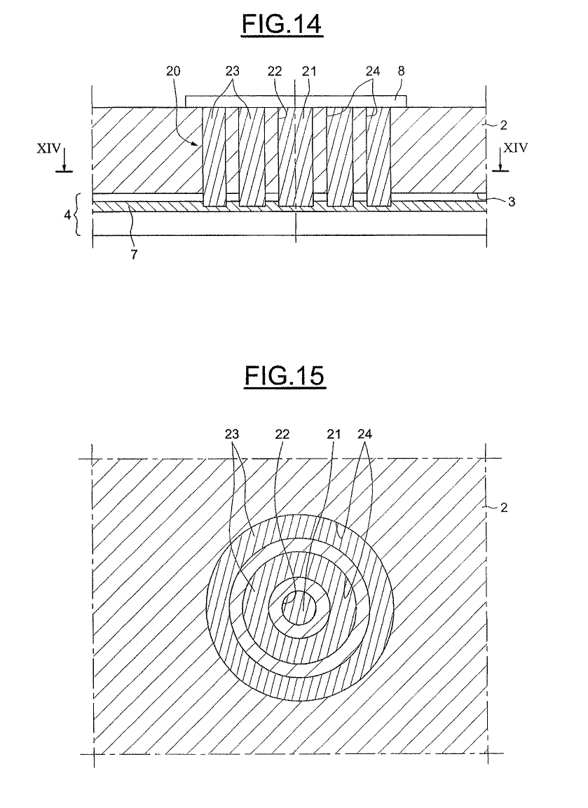

According to an alternative embodiment, illustrated in FIGS. 14 and 15, an electrical connection via 20, again designed for connecting a front pad 7 to a rear pad 8 through the substrate 2, may comprise a conducting central solid cylinder 21 made in a central hole 22 passing through the substrate 2 and one or more conducting coaxial cylindrical rings 23, for example two such rings, which are formed in a plurality of coaxial annular holes 24 made through the substrate 2.

The electrical connection vias 17 and 20 may be produced as described with reference to FIGS. 1 to 5 or as described with reference to FIGS. 6 to 11 with interposition of insulating rings between their conducting portions and the substrate 2.

According to an alternative embodiment, illustrated in FIG. 16, a semiconductor device 1 comprises an electrical connection via 25, connecting a front pad 7 of a front layer 4 to a rear pad 8, which may be produced on the side of the front face 3 of the substrate 2. As shown, this via 25 may comprise, in two annular holes 26, two coaxial conducting rings 27.

The electrical connection via 25 may be produced in the following manner.

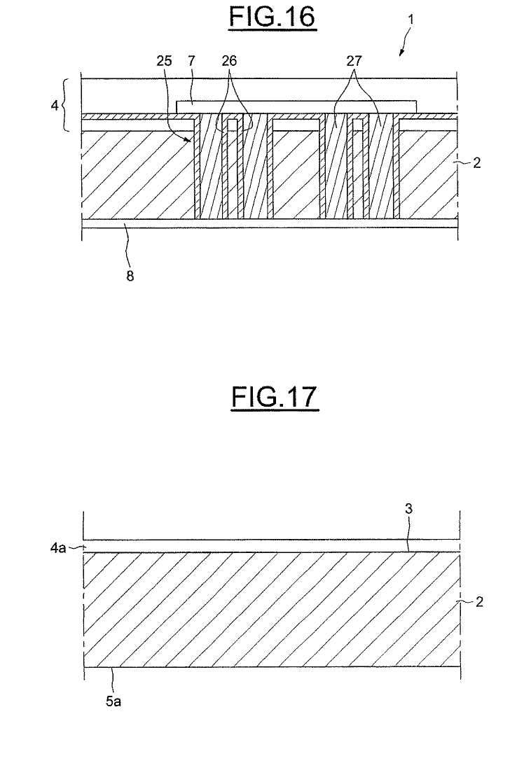

As shown in FIG. 17, starting with a thick substrate 2, integrated circuits produced on its front face 3, form a sublayer 4a.

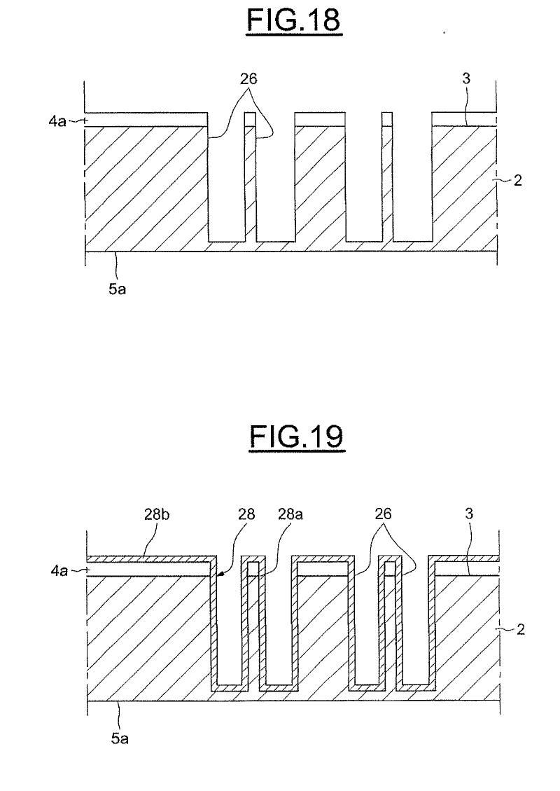

Next, as shown in FIG. 18, the blind annular holes 26 are produced through the sublayer 4a and into the substrate 2, without these holes reaching the rear face 5a of the substrate 2. The blind annular holes 26 are of course produced in a zone of the sublayer 4a which is free of integrated circuits.

Next, as shown in FIG. 19, an insulating layer 28 is deposited, a portion 28a of said layer covering the walls and the bottom of the blind annular holes 26 and a portion 28b of which covers the sublayer 4a.

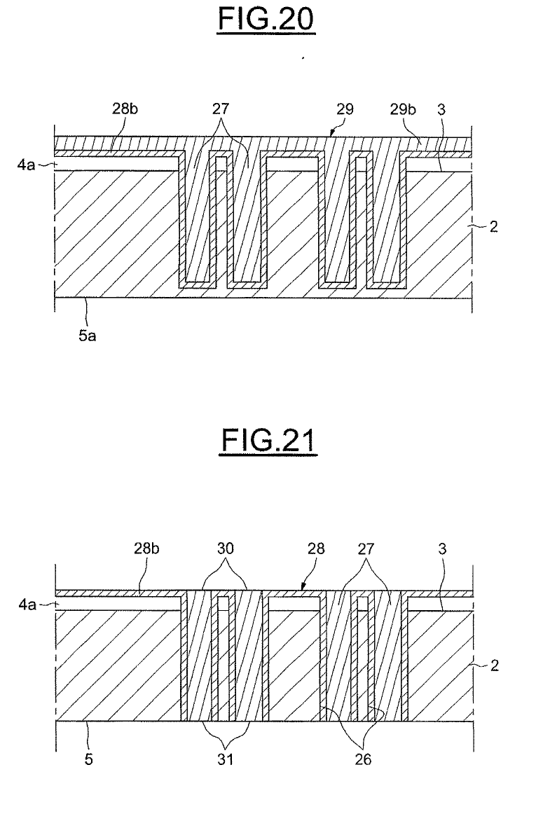

Next, as shown in FIG. 20, a conducting layer 29 is deposited which fills the blind annular holes 26, in order to form the conducting rings 27, and which have a portion 29b on the portion 28b of the insulating layer 28.

Next as shown in FIG. 21, the layer 29 undergoes a chemical-mechanical polishing (CMP) operation in order to remove its portion 29b down to the portion 28b of the layer 28, so as to form, in the same plane, front faces 30 of the conducting rings 27.

Next, as also shown in FIG. 21, the substrate 2 is thinned via its rear face until the conducting rings 27 are exposed and possibly trimmed, thereby forming the rear face 5 of the substrate 2 and, in the same plane, the radial rear faces 28 of the conducting rings.

After this, the interconnect means may be produced on the layer 28 in order to complete and form the layer 4, including the front pad 7 on the front faces 30 of the conducting rings 27 and to produce the interconnect means on the rear face 5, including the rear pad 8 on the rear faces 31 of the conducting rings 27.

In an alternative embodiment, the layer 4 could be completed and formed before the substrate 2 is thinned.

As follows from the above description, for producing an electrical connection via or a plurality of electrical connection vias, the holes made in the substrate may be produced collectively, in a single operation, when the conducting portions of the electrical connection vias may be produced collectively, in a single operation, and the polishing may be carried out collectively, in a single operation.

The structures of the electrical connection vias that have been described above may be particularly advantageous for reducing the skin effects in the material constituting them, or even for eliminating said effects, while limiting the electrical resistance of the vias. This enables the joule losses to be limited.

The skin depth is used to determine the width of the zone in which the current is concentrated in an electrical conductor. This depth enables the effective resistance at a given frequency to be calculated.

The skin depth is generally calculated by applying the following formula (A):

$$δ = \sqrt{\frac{2}{ωμσ}} = \sqrt{\frac{2 ρ}{ωμ}} ,$$

in which:
δ represents the skin depth in meters;
ω represents the angular frequency in radians per second (i.e. ω=2πf);
f represents the frequency of the current in hertz;
μ represents the magnetic permeability in henries per meter;
ρ represents the resistivity in ohms-meter (i.e. ρ=1/σ); and
σ represents the electrical conductivity in siemens per meter.

Thus, having chosen a material for producing the electrical connection vias of the examples described, the skin depth δ may be calculated according to the characteristics of this material and of the current that has to pass through the vias, by applying the above formula (A).

After this, a maximum radial thickness e attributed to the conducting rings and optional conducting central cylinders forming the electrical connection vias of the examples described may be chosen in such a way that this thickness e is at most equal to twice the calculated skin depth δ.

The present invention is not limited to the examples described above. Many other alternative embodiments are possible, for example by combining the various examples in other ways, without departing from the scope defined by the appended claims.

What is claimed is:

1. A process, comprising:
producing an annular hole in a substrate;
filling the annular hole with an electrically conductive material in order to obtain a conducting ring at least partly forming an electrical connection via through the substrate in order to make an electrical connection from one face of the substrate to another face of the substrate.

2. The process according to claim 1,
wherein producing comprises producing several concentric annular holes in the substrate; and
wherein filling comprises filling of the concentric annular holes with the electrically conductive material in order to obtain several conducting rings at least partly forming the electrical connection via.

3. The process according to claim 1, further comprising:
producing a central hole in the substrate which is coaxial with the annular hole; and
filling the central hole with the electrically conductive material in order to obtain a central cylinder which is coaxial with the conducting ring, the central cylinder and conducting ring at least partly forming the electrical connection via.

4. The process according to claim 1, comprising:
forming an auxiliary layer on one face of the substrate; and
producing the electrical connection via from the another face of the substrate, the electrical connection via extending up to or into the auxiliary layer.

5. The process according to claim 1, comprising:
producing the electrical connection via in a portion of a thickness of the substrate from one face of the substrate; and
removing a portion of the thickness of the substrate from the another face of the substrate in order to expose said electrical connection via.

6. The process according to claim 1, further comprising interposing an insulating material between the substrate and the electrical connection via.

7. The process according to claim 6, wherein interposing comprises:
lining the annular hole in the substrate with the insulating material before filling the annular hole with the electrically conductive material.

8. The process according to claim 1, wherein a radial thickness of each annular hole is at most twice a skin depth (δ) in the material forming the electrical connection via.

9. The process according to claim 3, wherein a diameter of the central hole is at most twice a skin depth (δ) in the material forming the electrical connection via.

10. Apparatus, comprising:
a substrate for a semiconductor device;
at least one via providing an electrical connection from one face of the substrate to another face of the substrate;
wherein the electrical connection via is made of an electrically conductive material;
wherein the electrical connection via comprises at least one conducting ring made in an annular hole passing through the substrate.

11. The apparatus according to claim 10, wherein said electrical connection via comprises several coaxially arranged conducting rings, these rings being made in several coaxial annular holes passing through the substrate.

12. The apparatus according to claim 10, wherein said electrical connection via comprises:
a conducting central cylinder; and
at least one conducting ring coaxial with said cylinder;
wherein the cylinder and ring are made in a central hole and an annular hole, respectively, passing through the substrate.

13. The apparatus according to claim 12, wherein a radial thickness of each conducting ring is at most twice a skin depth (δ) in a material forming the electrical connection via.

14. The apparatus according to claim 12, wherein a diameter of the conducting central cylinder is at most twice a skin depth (δ) in a material forming the electrical connection via.

15. The apparatus according to claim 10, further comprising, on one face of the substrate, an integrated circuit connected to said via.

16. Apparatus, comprising:
a substrate for a semiconductor device;
at least one via providing an electrical connection from one face to another face of the substrate;
wherein the via is made of an electrically conductive material;
wherein each portion of the via has a thickness at most twice a skin depth (δ) in a material forming the via.

17. The apparatus according to claim 16, further comprising, on one face of the substrate, an integrated circuit connected to said via.

18. A process, comprising:
producing an annular hole in a substrate;
filling the annular hole with an electrically conductive material in order to obtain a ring of the electrically conductive material.

19. The process according to claim 18, wherein producing comprises producing a blind annular hole in the substrate extending from a first side of the substrate.

20. The process according to claim 19, further comprising thinning the substrate from a second side of the substrate opposite the first side so as to expose a bottom of the ring of the electrically conductive material.

21. The process according to claim 18, further comprising lining the annular hole in the substrate with the insulating material before filling the annular hole with the electrically conductive material.

22. The process according to claim 18, wherein producing an annular hole comprises producing a plurality of coaxially arranged annular holes, and wherein filling the annular hole comprises filling the plurality of coaxially arranged annular holes in order to obtain a plurality of coaxially arranged rings of the electrically conductive material.

23. The process according to claim 18, further comprising:
producing a central hole in the substrate which is coaxial with the annular hole; and
filling the central hole with the electrically conductive material in order to obtain a central cylinder which is coaxial with the conducting ring.

24. The process according to claim 23 wherein the central cylinder of the electrically conductive material at least partly forms an electrical connection via extending through the substrate for making an electrical connection from a first side of the substrate to an opposed second side of the substrate.

25. The process according to claim 18 wherein the ring of the electrically conductive material at least partly forms an electrical connection via extending through the substrate for making an electrical connection from a first side of the substrate to an opposed second side of the substrate.
